(19) United States
(12) Patent Application Publication
(10) Pub. No.: US 2006/0163741 A1
(43) Pub. Date: Jul. 27, 2006

(54) TFT array panel and fabricating method thereof

(76) Inventors: Yang-ho Bae, Gyeonggi-do (KR); Je-hun Lee, Seoul (KR); Beom-seok Cho, Seoul (KR); Chang-oh Jeong, Gyeonggi-do (KR)

Correspondence Address: DLA PIPER RUDNICK GRAY CARY US, LLP, 2000 UNIVERSITY AVENUE, E. PALO ALTO, CA, 94303-2248, US

(21) Appl. No.: 11/328,820

(22) Filed: Jan. 9, 2006

(30) Foreign Application Priority Data
Jan. 7, 2005 (KR) 10-2005-0001797

(51) Int. Cl. H01L 23/48

(52) U.S. Cl. 257/763

(57) ABSTRACT

A TFT array panel including a lower aluminum layer, an aluminum nitride layer formed on the lower aluminum layer, and an upper aluminum layer formed on the aluminum nitride layer is presented. This TFT array panel including an aluminum wiring line reduces or even prevents the formation of a hillock that could create a short circuit. Also presented is a method of fabricating such TFT array panel.

### CROSS-REFERENCE TO RELATED APPLICATIONS

This application claims the benefit of Korean Patent Application No. 2005-0001797 filed on Jan. 7, 2005 in the Korean Intellectual Property Office, the disclosure of which is incorporated herein by reference.

### BACKGROUND OF THE INVENTION

1. Field of the Invention

The present invention relates to a thin film transistor (TFT) array panel and a fabricating method thereof, and more particularly to a thin film transistor (TFT) array panel including an aluminum nitride layer formed between aluminum layers and a fabricating method thereof.

2. Description of the Related Art

In a liquid crystal display (LCD), an LCD panel comprises a TFT array panel, a color filter array panel, and a liquid crystal sandwiched between the TFT array panel and the color filter array panel. As the LCD panel cannot emit light on its own, it is often used in conjunction with a backlight unit. Typically, the backlight unit is located behind the TFT array panel and emits light toward the TFT array panel. The transmittance of the light emitted from the backlight unit varies depending on the molecular arrangement of the liquid crystal.

Recently, the need for a wide-screen LCD having high definition and a high aperture ratio has been increasing. Accordingly, the length of the wiring lines in the LCD is getting longer while the wiring lines are getting narrower. A problem with this trend is that the high specific resistance of the wiring material may cause RC delay, thereby distorting a picture.

Hitherto, a metal such as chrome (Cr), molybdenum-tungsten alloy (MoW) or the like that has a high specific resistance of 10 μΩ/cm or more has been used for the wiring lines. However, the specific resistance of these materials is too high to be used for the wiring lines of the wide-screen LCD having a size of 20-inches or more. Accordingly, a wiring line having a relatively low specific resistance is desired.

Exemplary metals having a relatively low specific resistance include silver (Ag), copper (Cu), aluminum (Al), etc. Among these metals, silver and copper have poor adhesion property with a glass substrate of a TFT array panel. As for copper, it has a tendency to diffuse with the amorphous silicon in the semiconductor layer of the TFT, thereby damaging the TFT and lowering the specific resistance of the copper.

Due to the shortcomings of silver and copper described above, aluminum is generally used as the basic material for the wiring lines. Aluminum has many merits such as a low specific resistance of about 3 μΩ/cm, ease of forming the wiring lines, low-cost, etc.

However, aluminum is not without a problem. It has a tendency to form a hillock, which may cause a short circuit in the wiring lines. For example, the hillock formed on a gate wiring line penetrates a gate insulating layer and contacts a data wiring line, thereby causing a short circuit of the wiring lines.

Such a problem due to the hillock becomes aggravated as the aluminum wiring line gets thicker. Thus, search continues for a method of controlling the hillock formation when using aluminum in LCD wiring lines.

### SUMMARY OF THE INVENTION

Accordingly, it is an aspect of the present invention to provide a TFT array panel with an aluminum wiring line that does not suffer from hillock formation.

Another aspect of the present invention is a method of fabricating a TFT array panel on which a hillock is prevented from growing.

The foregoing and/or other aspects of the present invention can achieved by providing a TFT array panel comprising a lower aluminum layer; an aluminum nitride layer formed on the lower aluminum layer; and an upper aluminum layer formed on the aluminum nitride layer.

The upper aluminum layer may have a thickness of 2,500 Å or below, or a thickness of 1,500 Å or below. The thickness sum of the lower and upper aluminum layers may be more than 4,000 Å. The thickness of the aluminum nitride layer may be more than 5% of the thickness of the lower aluminum layer. In some cases, the thickness of the aluminum nitride layer ranges from 100 to 400 Å.

The TFT array panel may also include a molybdenum layer formed on the upper aluminum layer.

The aluminum nitride layer may contain 0.01 through 60 mole % nitrogen.

The foregoing and/or other aspects of the present invention can be achieved by providing a TFT array panel comprising a gate wiring line; a data wiring line; and at least one of the gate and data wiring lines comprising a lower aluminum layer, an aluminum nitride layer, an upper aluminum layer, formed in sequence.

The foregoing and/or other aspects of the present invention can be achieved by providing a method of fabricating a TFT array panel. The method entails depositing a lower aluminum layer on an insulating substrate; depositing an aluminum nitride layer on the lower aluminum layer in a nitrogen precursor gas atmosphere; and depositing an upper aluminum layer on the aluminum nitride layer.

A molybdenum layer may be deposited on the upper aluminum layer.

The upper aluminum layer, the aluminum nitride layer, and the lower aluminum layer may be continuously deposited.

The aluminum nitride layer may be deposited by a sputtering method.

The nitrogen precursor gas may be at least one of nitrogen, ammonia, nitric oxide, and nitric dioxide. The nitrogen precursor gas may be provided together with argon.

The foregoing and/or other aspects of the present invention can be achieved by providing a liquid crystal display comprising a first substrate comprising a gate wiring line and a data wiring line, at least one of which comprises a lower aluminum layer, an aluminum nitride layer, and an upper aluminum layer that are formed in sequence, a second substrate facing the first substrate; and a liquid crystal layer placed between the first substrate and the second substrate.

According to an embodiment of the present invention, an aluminum nitride layer is interposed in the aluminum wiring line so as to prevent the aluminum from moving, thereby preventing the hillock from growing.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a cross sectional view showing aluminum wiring lines according to a first embodiment of the present invention;

FIG. 2 is a cross sectional view showing an aluminum wiring line according to a second embodiment of the present invention;

FIG. 3 is a plan view of a TFT array panel according to the first embodiment of the present invention;

FIG. 4 is a cross sectional view of the TFT array panel, taken along line IV-IV of FIG. 3;

FIGS. 5 through 8 are sectional views showing a process of fabricating the TFT array panel according to the first embodiment of the present invention;

FIG. 9 is a plan view of a TFT array panel according to the second embodiment of the present invention;

FIG. 10 is a cross sectional view of the TFT array panel, taken along line X-X of FIG. 9;

FIG. 11 is a cross sectional view of the TFT array panel, taken along line XI-XI of FIG. 9; and

FIGS. 12A through 19B are sectional views showing a process of fabricating the TFT array panel according to the second embodiment of the present invention.

### DETAILED DESCRIPTION OF PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

The cause of the hillock formed on a wiring line is as follows. On the way of fabricating the TFT array panel, an insulating layer, a semiconductor layer, etc. are deposited through plasma enhanced chemical vapor deposition (PECVD) after forming an aluminum wiring line. The PECVD is performed at high temperature, and thus compressive stress is applied to aluminum. At this time, the aluminum moves along its surface, particularly, along a grain boundary and grows to lateral side or upper side of the aluminum wiring line.

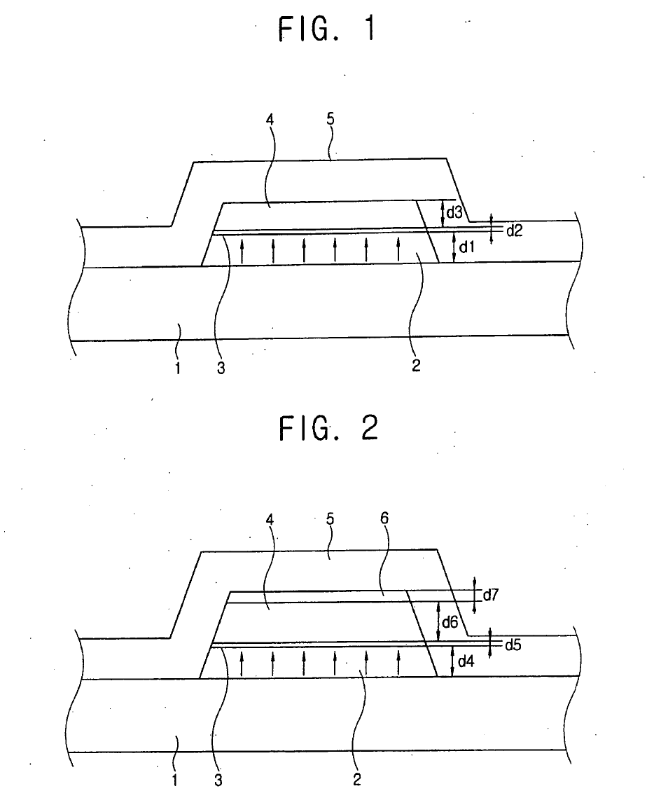

FIG. 1 is a cross sectional view showing aluminum wiring lines according to a first embodiment of the present invention.

Referring to FIG. 1, an aluminum wiring line according to the first embodiment of the present invention is realized by a triple-layer structure including a lower aluminum layer 2, an aluminum nitride layer 3, and an upper aluminum layer 4. Here, the aluminum wiring line is formed on a substrate 1, and the aluminum wiring line is covered with an insulating layer 5.

The aluminum nitride layer 3 prevents the aluminum of the lower aluminum layer 2 from moving and decreases the growth of a hillock. Preferably, the thickness d2 of the aluminum nitride layer 3 is more than 5% of the thickness d1 of the lower aluminum layer 2. When the thickness d2 of the aluminum nitride layer 3 is too large, the aluminum nitride layer 3 is likely to function as an insulating layer. Therefore, the thickness d2 of the aluminum nitride layer 3 is preferably less than 30% of the thickness d1 of the lower aluminum layer 2. When the aluminum nitride layer 3 functions as the insulating layer, the lower aluminum layer 2 and the upper aluminum layer 4 are electrically insulated from each other, so that the specific resistance of the aluminum wiring line increases. In more detail, the aluminum nitride layer 3 preferably has a thickness of 100 through 400 Å. Meanwhile, the aluminum nitride layer 3 preferably contains nitrogen by 0.01 through 60 atom %. When nitrogen is less than 0.01 atom %, the aluminum nitride layer 3 cannot properly prevent aluminum of the lower aluminum layer 2 from moving. On the other hand, when nitrogen is more than 60 atom %, the aluminum nitride layer 3 may function as the insulating layer. According to an embodiment of the present invention, the aluminum nitride layer 3 may further contain carbon, oxygen or the like.

Preferably, the thickness d4 of the upper aluminum layer 4 is less than 1,500 Å. Movement of aluminum of the upper aluminum layer 4 can cause a hillock penetrating the insulating layer 5. However, when the thickness d4 of the upper aluminum layer 4 is less than 1,500 Å, no hillock is formed that is big enough to cause a short circuit. Further, the thickness sum d1+d3 of the lower aluminum layer 2 and the upper aluminum layer 3 is preferably more than 4,000 Å in order to make the wiring line have low resistance satisfying a wide screen and high resolution of the display apparatus. The thickness sum d1+d3 of the lower aluminum layer 2 and the upper aluminum layer 3 can be further increased by capping the aluminum layer with a metal such as a molybdenum layer.

FIG. 2 is a cross sectional view showing aluminum wiring lines according to a second embodiment of the present invention.

Referring to FIG. 2, a molybdenum layer 6 is additionally formed on the upper aluminum layer 4. In the second embodiment, the relationship between the thickness d4 of the upper aluminum layer 4, the thickness d5 of the aluminum nitride layer 3, and constituent of the aluminum nitride layer 3 is the same as those of the first embodiment.

According to the second embodiment of the invention, the thickness d6 of the upper aluminum layer 4 can be larger than that of the first embodiment because the upper aluminum layer 4 is capped with the molybdenum layer 6 to prevent aluminum of the upper aluminum layer 4 from moving or deforming. If the thickness d6 of the upper aluminum 4 is too large, it is not suitable for the molybdenum layer 6 to prevent the aluminum in the upper aluminum layer 4 from moving or deforming. Therefore, the thickness d6 of the upper aluminum layer 4 is preferably less than 2,500 Å.

Further, the thickness sum d4+d6 of the lower aluminum layer 2 and the upper aluminum layer 4 is preferably more than 4,000 Å.

Further, the thickness d7 of the molybdenum layer 6 preferably has a thickness of 300 through 500 Å. In some embodiments, the molybdenum layer 6 may be substituted by a molybdenum alloy layer, a nickel layer, a chrome layer, or a titanium layer. Here, the molybdenum layer 6 not only prevents the aluminum of the upper aluminum layer 4 from moving or deforming but also has low contact resistance with a transparent conductively layer. The wiring line contacts the transparent conductive layer, which may contain materials such as such as indium tin oxide (ITO) or indium zinc oxide (IZO), to be connected to a pixel electrode (to be described later) or the like. In the case of aluminum, the contact between aluminum and the transparent conductive layer is poor, so that a problem arises in signal transmission. On the other hand, when the molybdenum layer 6 is formed on the wiring line like the second embodiment, the transparent conductive layer is in contact with the molybdenum layer 6, thereby solving the problem in signal transmission.

In the foregoing embodiments, variations of the aluminum wiring line may be used. For example, the aluminum layer and the aluminum nitride layer may be alternatively formed as a a structure with four or more layers.

Hereinbelow, a method of forming the aluminum wiring line according to the first embodiment of the present invention will be described.

First, the lower aluminum layer 2 is formed on the substrate 1. The lower aluminum layer 2 may be formed by a sputtering method.

In the sputtering method, argon gas is injected into a chamber provided with a target electrode made of aluminum to which high voltage is applied, and then plasma discharge is performed. Then, positive argon ions excited by the plasma discharge separate aluminum atoms from the target electrode, and the aluminum atoms are attached to the substrate and grown as a thin film.

When the lower aluminum layer 2 has a desired thickness, a nitric source gas is injected into the chamber, and then the aluminum nitride layer 3 is grown in a nitrogen atmosphere. As for the nitrogen source gas, nitrogen (N₂), ammonia (NH₄), nitric oxide (NO), nitrogen dioxide (NO2), etc. may be used. When one or more of these nitrogen source gases are injected into the chamber, nitrogen is deposited together with aluminum, thereby forming the aluminum nitride layer 3.

When the aluminum nitride layer 3 has a desired thickness, the nitrogen source gas is stopped from being injected into the chamber, and the upper aluminum layer 4 is deposited. If necessary, there may be added a process of removing the nitrogen source gas that remains in the chamber.

The above-described processes are continuously performed in the same chamber, so that it is not necessary to transport the substrate 1 for different parts of the process. The aluminum nitride layer 3 is easily formed by just injecting the nitrogen source gas into the chamber.

Thereafter, the aluminum layers 3 and 4 are patterned to form the aluminum wiring line, and then covered with the insulating layer 5. Even though the aluminum wiring line is heated to a high temperature while the insulating layer 5 is formed, the aluminum nitride layer 3 prevents the aluminum of the lower aluminum layer 2 from moving/deforming to form a hillock.

A TFT array panel according to an embodiment of the present invention, and a method of fabricating the same will be described.

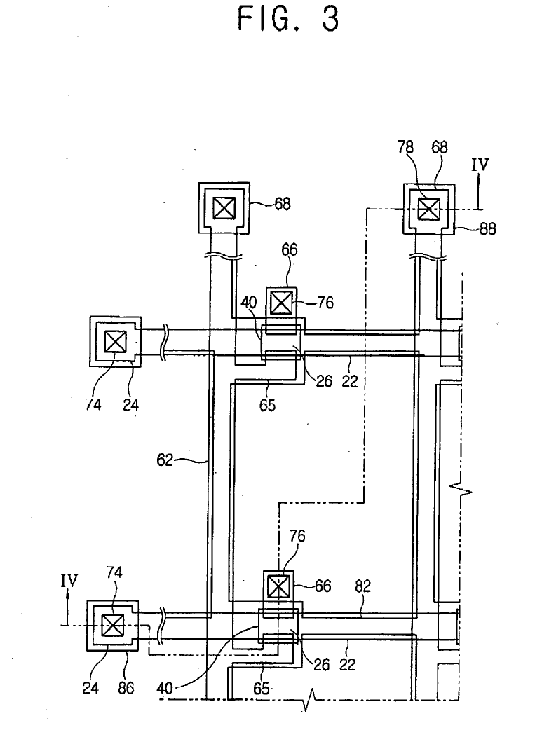

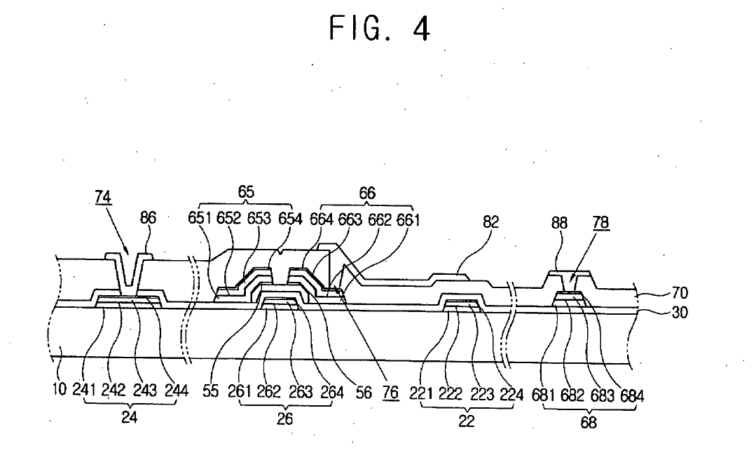

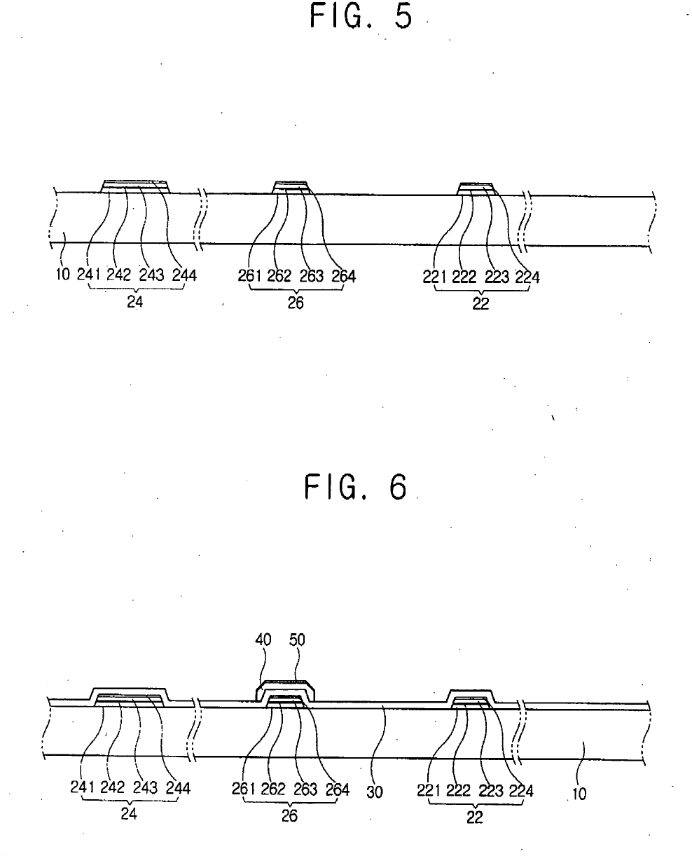

FIG. 3 is a plan view of a TFT array panel according to the first embodiment of the present invention; FIG. 4 is a cross sectional view of the TFT array panel, taken along line IV-IV of FIG. 3; and FIGS. 5 through 8 are sectional views showing a process of fabricating the TFT array panel according to the first embodiment of the present invention.

On the insulating substrate 10 is formed a gate wiring line 22, 24, 26, wherein the gate wiring line is of a four-layered structure including a lower aluminum layer 221, 241, 261, an aluminum nitride layer 222, 242, 262, an upper aluminum layer 223, 243, 263, and a molybdenum layer 224, 244, 264.

Each of the gate wiring lines 22 and 26 includes a gate line 22 formed in a horizontal direction and a gate electrode 26 included in a thin film transistor and connected to the gate line 22, wherein the width of one end portion 24 of the gate line 22 is enlarged to be connected with an external circuit.

Further, on the first insulating substrate 10 is formed a gate insulating layer 30 made of silicon nitride (SiNx) or the like, and covering the gate wiring line 22, 24, 26.

On the gate insulating layer 30 of the gate electrodes 26 is formed a semiconductor layer 40 made of amorphous silicon or the like. On the semiconductor layer 40 are formed ohmic contact layers 55 and 56 made of n+ hydrogenated amorphous silicon highly-doped with n-type impurities.

On the ohmic contact layers 55 and 56 and the gate insulating layer 30 is formed a data wiring line 65, 66, 68, wherein the data wiring line 65, 66, 68 has the same four-layered structure including a lower aluminum layer 651, 661, 681, an aluminum nitride 652, 662, 682, an upper aluminum layer 653, 663, 683, and a molybdenum layer 654, 664, 684.

The data line 62 is not shown but has the four-layered structure like the data wiring line 65, 66, 68.

The data wiring lines 62, 65, 66, 68 include a data line 62 formed in a vertical direction and crossing the gate line 22 to define a pixel, a source electrode 65 branching from the data wiring line 62 and extending over the ohmic contact layer 55, and a drain electrode 66 separated from the source electrode 65 and formed over the ohmic contact layer 56. The drain electrode 66 is positioned across the gate electrode 26 from the source electrode 65. The width of one end 68 of the data line 62 is enlarged to be connected with the external circuit.

Further, a passivation layer 70 is formed on the data wiring lines 62, 65, 66, 68 and a portion of the semiconductor layer 40 that is not covered with the data wiring lines 62, 65, 66, 68, wherein the passivation layer is made of a SiNx layer, an a-Si:C:O layer, a-Si:O:F layer (low dielectric CVD layer), an acryl-based organic insulating layer, or etc. The a-Si:C:O layer and the a-Si:O:F layer are formed through PECVD (plasma enhanced chemical vapor deposition), and has a low dielectric constant of 4 or below (i.e., the dielectric constant thereof ranges from 2 to 4). Thus, a parasitic capacitance problem does not arise in the a-Si:C:O or a-Si:O:F layer even though its thickness is relatively thin. Further, the a-Si:C:O and a-Si:O:F layers are excellent in step coverage, contact property with other layers. Also, each of the a-Si:C:O and a-Si:O:F layers is an inorganic CVD layer and therefore has good heat-resistance property as compared with an organic dielectric layer. Besides, a deposition rate and an etching rate of the a-Si:C:O layer and the a-Si:O:F layer are four to ten times higher than those of SiNx, so that the a-Si:C:O layer and the a-Si:O:F layer have the advantage of short process time.

The passivation layer 70 has a contact hole 76 through which the drain electrode 66 is exposed, a contact hole 78 through which an end portion 68 of the data line is exposed, and a contact hole 74 through which an end portion 24 of the gate line and the gate insulating layer 30 are exposed.

On the passivation layer 70 is formed a pixel electrode 82 electrically connected with the drain electrode 66 through the contact hole 76 and located on a pixel region. Further, on the passivation layer 70 are formed contact subsidiary parts 86, 88 connected to the end portion 24 of the gate line and the end portion 68 of the data line through the contact hole 74 and 78, respectively. Here, the pixel electrode 82 and the contact subsidiary parts 86, 88 are made of a transparent conductive layer such as ITO (indium tin oxide) or IZO (indium zinc oxide). That is, the drain electrode 82 contacts the pixel electrode 82 through the molybdenum layer 664.

Referring to FIGS. 3 and 4, the pixel electrode 82 overlaps the gate line 22 to thereby form a storage capacitor. In case where the capacitance of the storage capacitor is not sufficient, a storage capacitor line assembly may be additionally provided at the same level as the gate wiring line 22, 24, 26.

Further, the pixel electrode 82 can overlap the data lines 62 to thereby maximize an aperture ratio. Even though the pixel electrode 82 overlaps the data line 62 in order to maximize the aperture ratio, the parasitic capacitance problem arising between the pixel electrode 82 and the data line 62 can be ignored as long as the passivation layer 70 is made of the low dielectric CVD layer.

A method of fabricating the TFT array panel according to the first embodiment is as follows. As shown in FIG. 5, on the insulating substrate 10 is deposited the four-layered gate metal structure that includes the lower aluminum layer 221, 241, 261, the aluminum nitride layer 222, 242, 262, the upper aluminum layer 223, 243, 263, and the molybdenum layer 224, 244, 264. Thereafter, the gate metal layer is patterned by photolithography using a mask, to thereby form gate wiring lines 22, 24, 26. The gate wiring lines 22, 24, 26 include the gate lines 22 and the gate electrodes 26, and extends in a transverse direction.

Referring to FIG. 6, the gate insulating layer 30 made of silicon nitride, the semiconductor layer 40 made of amorphous silicon, and a doped amorphous silicon layer 50 are sequentially deposited onto the insulating substrate 10. The semiconductor layer 40 and the doped amorphous silicon layer 50 are patterned by photolithography using a mask, thereby forming the semiconductor layer 40 and the ohmic contact layer 50 like an island on the gate insulating layer 30 over the gate electrode 26.

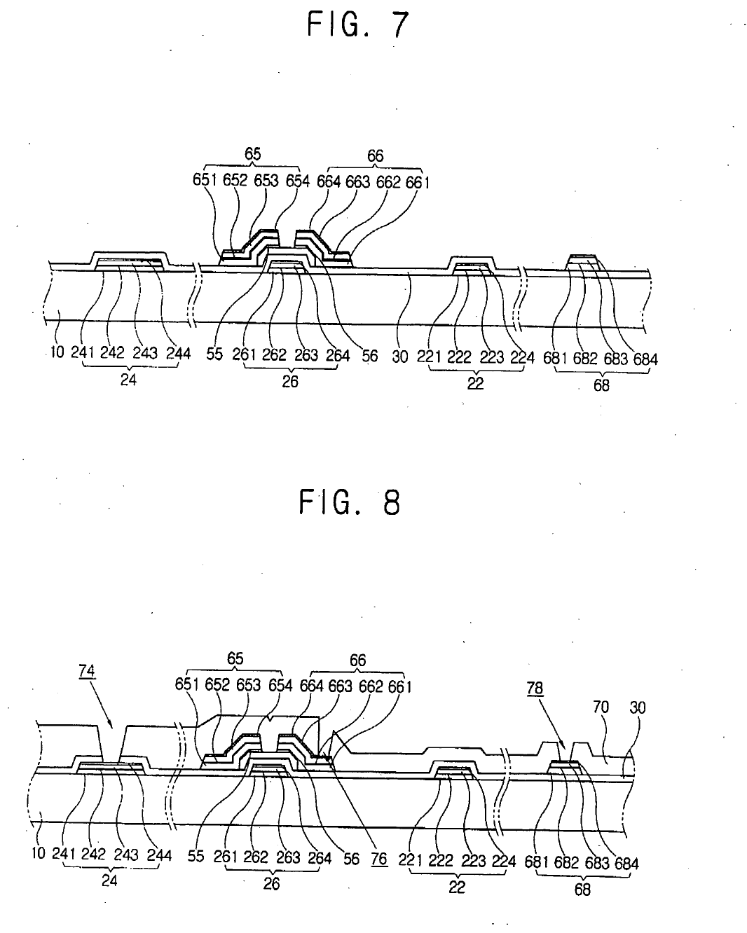

Referring to FIG. 7, the four-layered second data metal structure including the lower aluminum layer 621, 651, 661, the aluminum nitride layer 622, 652, 662, the upper aluminum layer 623, 653, 663, the molybdenum layer 624, 654, 664 is deposited and patterned by photolithography using a mask, to thereby form the data wiring line. The data wiring line includes the data line 62 intersecting the gate line 22, the source electrode 65 connected to the data line 62 and extending over the gate electrode 26, and the drain electrode 66 isolated from the source electrode 65 and positioned across the gate electrode 26 from the source electrode 65.

Subsequently, the doped amorphous silicon layer 50 (see FIG. 5) is etched at a region where the data wiring lines 62, 65, 66, 68 are not deposited, thereby being separated with respect to the gate electrode 26 and exposing the semiconductor layer 40 between the doped amorphous silicon layers 55 and 56. Additionally, an oxygen plasma can be applied to stabilize the surface of the exposed semiconductor layer 40.

Then, referring to FIG. 8, the passivation layer 70 is formed by growing a silicon nitride layer, an a-Si:C:O layer, or an a-Si:C:F layer through the CVD method, or by coating organic insulating material.

Then, the passivation layer 70, together with the gate insulating layer 30, is patterned by photolithography, thereby forming the contact holes 74, 76, 78 through the end portion 24 of the gate line, the drain electrode 66, and the end portion 68 of the data line, respectively.

Referring to FIGS. 3 and 4, the ITO layer or the IZO layer is deposited and etched using photolithography, thereby forming the pixel electrode 82 electrically connected to the drain electrode 66 through the contact hole 76 and forming the contact subsidiary parts 86, 88 respectively connected to the end portion 24 of the gate line and the end portion 68 of the data line through the contact holes 74, 78. Preferably, nitrogen gas is used in a pre-heating process before depositing the ITO layer or the IZO layer.

The above-described first embodiment employs five masks in fabricating the TFT array panel. The following second embodiment employs four masks.

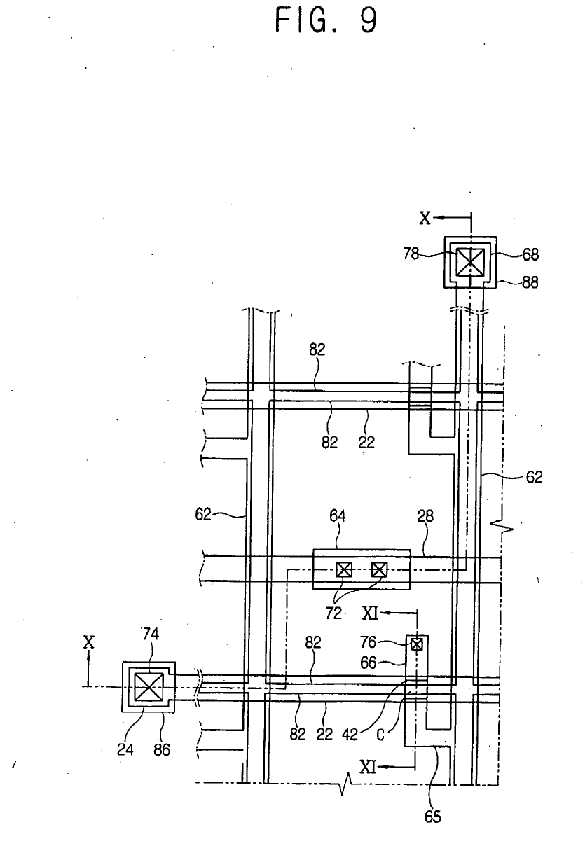

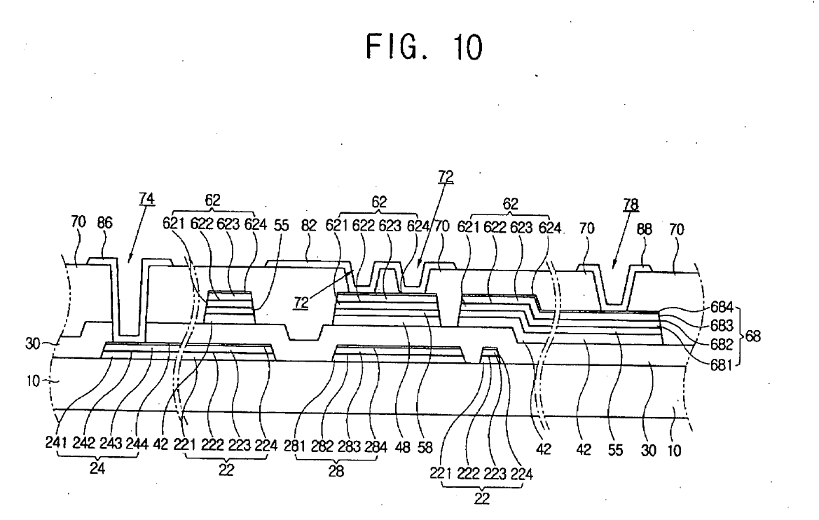

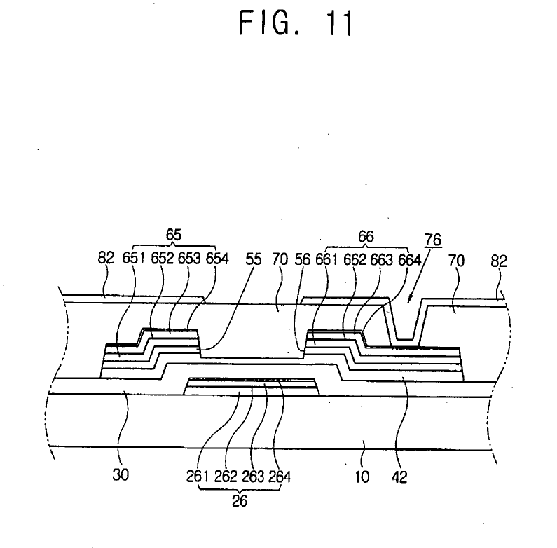

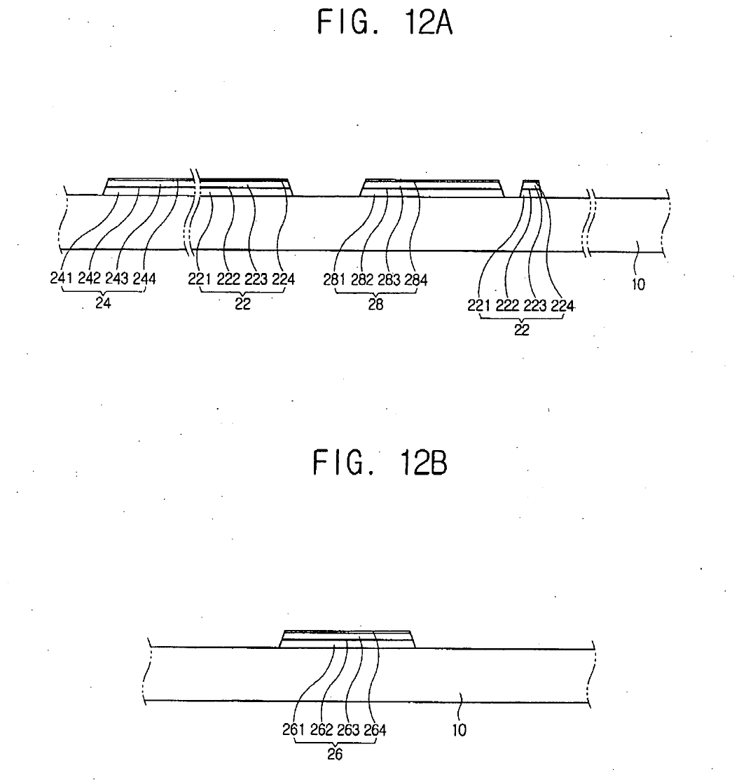

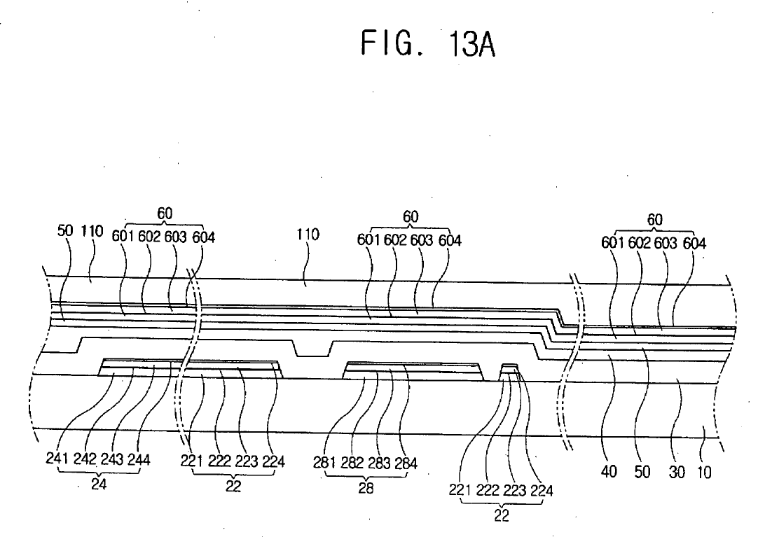

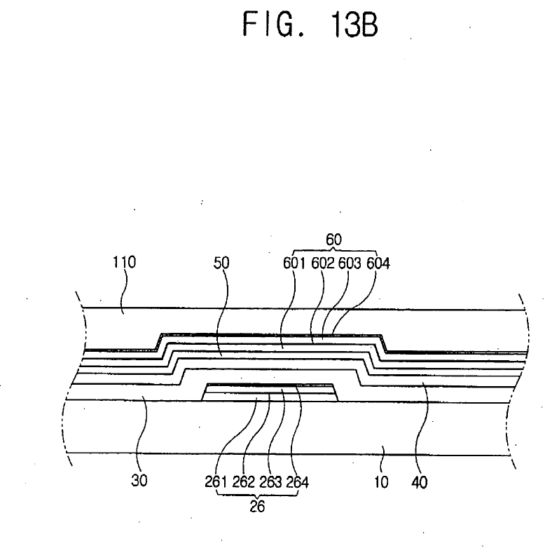

FIG. 9 is a plan view of a TFT array panel according to a second embodiment of the present invention, FIG. 10 is a cross sectional view of the TFT array panel, taken along line X-X of FIG. 9; FIG. 11 is a cross sectional view of the TFT array panel, taken along line XI-XI of FIG. 9; and FIGS. 12A through 19B are sectional views showing a process of fabricating the TFT array panel according to the second embodiment of the present invention.

Like the first embodiment, on the insulating substrate 10 is formed the gate wiring lines 22, 24, 26 having a four-layered structure including the lower aluminum layer 221, 241, 261, the aluminum nitride layer 222, 242, 262, an upper aluminum layer 223, 243, 263, and the molybdenum layer 224, 244, 264.

Further, on the insulating substrate 10 is formed a storage electrode line 28 in parallel with the gate line 22. Also, the storage electrode line 28 has a four-layered structure like the gate wiring lines 22, 24, 26. The storage electrode line 28 overlaps a storage capacitor conductive pattern 64 connected to the pixel electrode 82 (to be described later), and forms a storage capacitor enhancing the electrical potential storage capacitance of a pixel. If the storage capacitance owing to the overlap of the pixel electrode 82 with the gate line 22 is sufficient, the storage electrode line 28 can be omitted. Generally, voltage applied to the storage electrode line 28 is equal to voltage applied to a common electrode of a top substrate.

On the gate wiring lines 22, 24, 26 and the storage electrode line 28 is formed the gate insulating layer 30 made of silicon nitride (SiNx) or the like, thereby covering the gate wiring lines 22, 24, 26 and the storage electrode line 28.

On the gate insulating layer 30 are formed semiconductor patterns 42 and 48 made of a semiconductor such as hydrogenated amorphous silicon or the like. On the semiconductor patterns 42 and 48 is formed an ohmic contact pattern or intermediate layer patterns 55, 56, 58, which are made of amorphous silicon or the like highly doped with n-type impurities such as phosphorous (P).

On the ohmic contact layer 55, 56 and 58 are formed data wiring lines 62, 64, 65, 66, 68 having the four-layered structure including the lower aluminum layer 621, 641, 651, 661, 681 the aluminum nitride layer 622, 642, 652, 662, 682 the upper aluminum layer 623, 643, 653, 663, 683 and the molybdenum layer 624, 644, 654, 664, 684. The data wiring line comprises a data line portion 62, 68, 65 extending in a vertical direction. The data line portion 62, 68, 65 comprise a data line 62 having an end portion 68 to receive an external video signal and a source electrode 65 of the thin film transistor branching from the data line 62. A drain electrode 66 of the thin film transistor separated from the data line portion 62, 68, 65 and opposite to the source electrode 65 with respect to the gate electrode 26 or TFT channel portions C. The storage capacitor conductive pattern 64 is disposed on the storage electrode line 28. If the storage electrode line 28 is not provided, the storage capacitor conductive pattern 64 can be omitted.

The ohmic contact patterns 55, 56, 58 lower the contact resistance between the underlying semiconductor patterns 42, 48 and the overlying data wiring lines 62, 64, 65, 66, 68, and have the same shape as the data wiring lines 62, 64, 65, 66, 68. That is, the ohminc contact pattern 55 located under the data line 62, 68, 65 has the same shape as the data lines 62, 68, 65; the ohmic contact pattern located under the data wiring line 66 has the same shape as the drain electrodes 66; and the ohmic contact pattern located under the data wiring line 64 has the same shape as the storage capacitor conductive pattern 64.

The semiconductor patterns 42, 48 are similar to the patterns in the data wiring line 62, 64, 65, 66, 68 and the ohmic contact patterns 55, 56, 58 except for the TFT channel portions C. In more detail, the storage capacitor semiconductor pattern 48, the storage capacitor conductive pattern 64, and the storage capacitor ohmic contact pattern 58 are similar to each other. The TFT semiconductor pattern 42 differs in shape from the data wiring line and the other portions of the ohmic contact patterns. That is, the data wiring lines 62, 68, 65 at the TFT channel portion C, particularly the source electrode 65 and the drain electrode 66, are separated from each other. Likewise, the data line intermediate layer pattern 55 and the drain electrode ohmic contact pattern 56 are separated from each other. However, the TFT semiconductor pattern 42 continuously extends at the TFT channel portion C without separation, thereby forming the channel of the thin film transistor.

On the data wiring lines 62, 64, 65, 66, 68 is formed the passivation layer 70 made of silicon nitride; a-Si:C:O layer or a-Si:O:F layer (low dielectric layer) deposited by the PECVD method; or organic insulating layer. The passivation layer 70 has contact holes 76, 78, 72 through which the drain electrodes 66, the end portion 68 of the data line, and the storage capacitor conductive pattern 64 are exposed respectively. Further, the passivation layer 70 has a contact hole 74. The contact hole 74 penetrates the gate insulating layer 30 and exposes the end portion 24 of the gate line 22. On the passivation layer 70 is formed the pixel electrode 82 to receive a video signal from the thin film transistors and generate electric field together with an upper electrode (not shown). The pixel electrode 82 is made of a transparent conductive material such as ITO, IZO or the like. The pixel electrode 82 is physically and electrically connected to the drain electrode 66 via the contact hole 76, thereby receiving the video signal. Here, the pixel electrode 82 overlaps the neighboring gate line 22 and the neighboring data line 62 to enhance the aperture ratio. In another embodiment, the pixel electrode 82 may not overlap the neighboring gate line 22 and the neighboring data line 62. Further, the pixel electrode 82 is electrically connected to the storage capacitor conductive pattern 64 through the contact hole 72 and transmits the video signal to the storage capacitor conductive pattern 64. Contact subsidiary parts 86, 88 are formed over the end portion 24 of the gate line and the end portion 68 of the data line, and connected to both the end portion 24 of the gate line and the end portion 68 of the data line through the contact holes 74, 78, respectively. The contact subsidiary parts 86, 88 enhance the adhesion of the end portions 24, 68 to external circuits and protect the end portions 24, 68, respectively. Also, the contact subsidiary parts 86, 88 are made of a transparent conductive layer.

A method of fabricating the TFT array panel according to the second embodiment of the present invention is as follows. As shown in FIGS. 12A through 12B, a gate metal layer having a four-layered structure comprising a lower aluminum layer 221, 241, 261, 281, an aluminum nitride layer 222, 242, 262, 282, an upper aluminum layer 223, 243, 263, 283, a molybdenum layer 224, 244, 264, 284 is deposited like that of the first embodiment and patterned by the photolithography to form the gate wiring line including the gate line 22, the gate electrode 26 and the storage capacitor electrode 28. At this time, the width of one end portion 24 of the gate line 22 is enlarged to be connected with an external circuit.

Thereafter, referring to FIGS. 13A and 13B, the gate insulating layer 30 having a thickness of about 1500 Å to about 5000 Å, the semiconductor layer 40 having a thickness of about 500 Å to about 2000 Å and the intermediate layer 50 having a thickness of about 300 Å to about 600 Å are sequentially deposited by the CVD method. The conductive layer 60 having a four-layered structure including a lower aluminum layer 601, an aluminum nitride layer 302, an upper aluminum 603, and a molybdenum layer 604 is deposited to form the data wiring line. Then, a photoresist film 110 having a thickness of about 1 μm to about 2 μm is coated onto the conductive layer 60.

Referring to FIGS. 13A and 13B, the photoresist film 110 is exposed to light through a mask, and developed to thereby form a photoresist pattern 112, 114. At this time, a first photoresist pattern portion 114 placed at the TFT channel portion C between the source and drain electrodes 65, 66 is established to have a thickness smaller than that of a second photoresist pattern portion 112 placed at a data wiring line portion A in which the data wiring line 62, 64, 65, 66, 68 will be formed. On the other hand, the photoresist pattern portion 110 placed at the other portion B is all removed. At this time, the thickness ratio of the first photoresist pattern portion 114 placed at the TFT channel portion C to the second photoresist pattern portion 112 remaining at the data wiring line portion A should be controlled depending upon the processing conditions in the subsequent etching process. For example, the thickness of the first photoresist pattern portion 114 is formed to be about ½ or less of that of the second photoresist pattern portion 112. Preferably, the thickness of the first photoresist pattern portion 114 can be formed to be about 4000 Å or less.

According to an embodiment of the present invention, various masks can be used to differentiate the thickness of the photoresist film 110. The masks may include a slit pattern, a lattice pattern or a semitransparent film to control the light transmissivity in the portion A.

In the case of using the slit pattern or the lattice pattern, it is preferable that the width of slit or lattice should be smaller than the light decomposition capability of a light exposure apparatus. If a semitransparent film is sued, the semitransparent film can have at least two thin films of different transmissivities or thicknesses to adjust the transmissivity of light while the mask is formed.

When the photoresist film is exposed to light through the mask, polymers of the photoresist film 110 directly exposed to light are completely decomposed. Further, the polymers of the photoresist film corresponding to the slit pattern or the semitransparent film of the mask are decomposed at some degree. However, the polymers of the photoresist film blocked from the mask are not decomposed. When the photoresist film 110 is developed after exposure to light, the portions where the polymers are not decomposed remain in varying thicknesses depending on the degree of molecular decomposition that took place in accordance with the exposure to the light. The light exposing time should not be so long as to prevent all the molecules of the photoresist film from being decomposed.

Alternatively, the first photoresist pattern portion 114 having a relatively thin thickness can be formed using a photoresist film capable of reflow. The photoresist film is exposed to light through a usual mask with a light transmission portion and a light interception portion. Then, the light-exposed photoresist film is developed, and it reflows so that the film portion is partially transferred to the non-film area, thereby forming such a thin photoresist pattern 114.

Thereafter, the first photoresist pattern portion 114 and its underlying layers, that is, the conductive layer 60, the intermediate layer 50, and the semiconductor layer 40, are etched. At this time, the data line and its underlying layers are left over at the data wiring line portion A, and only the semiconductor layer 40 remains at the TFT channel portion C. Further, the conductive layer 60, the intermediate layer 50, and the semiconductor layer 40 are all removed at the other portion B, thereby exposing the underlying gate insulating layer 30.

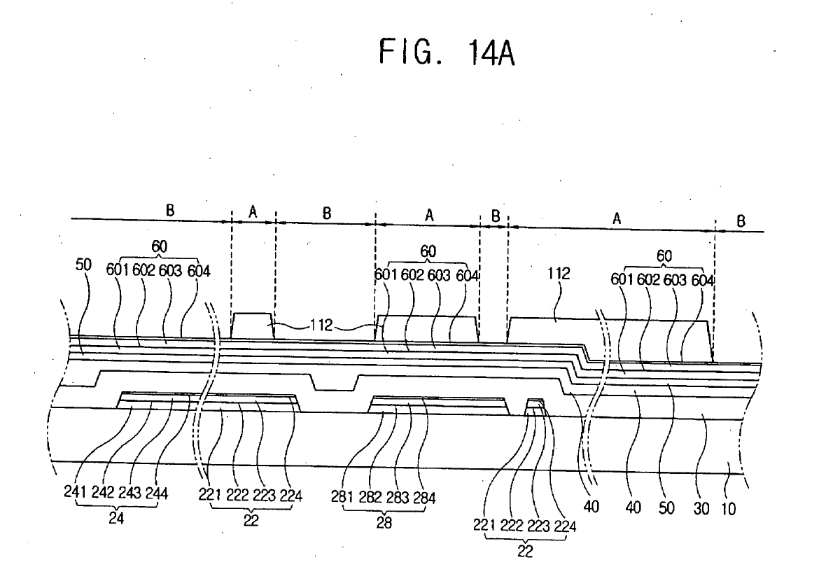

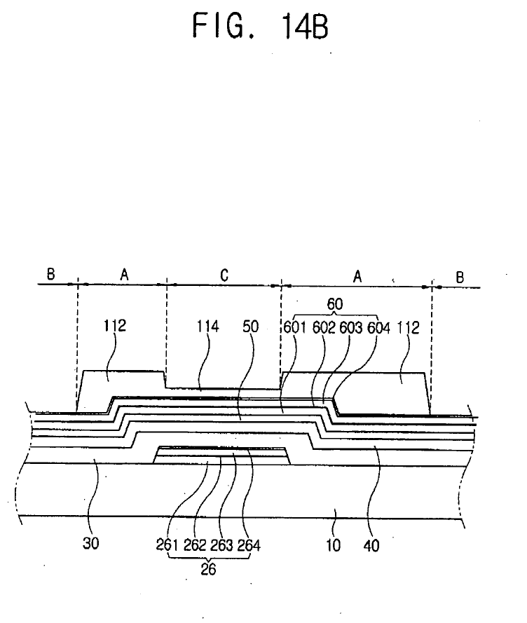

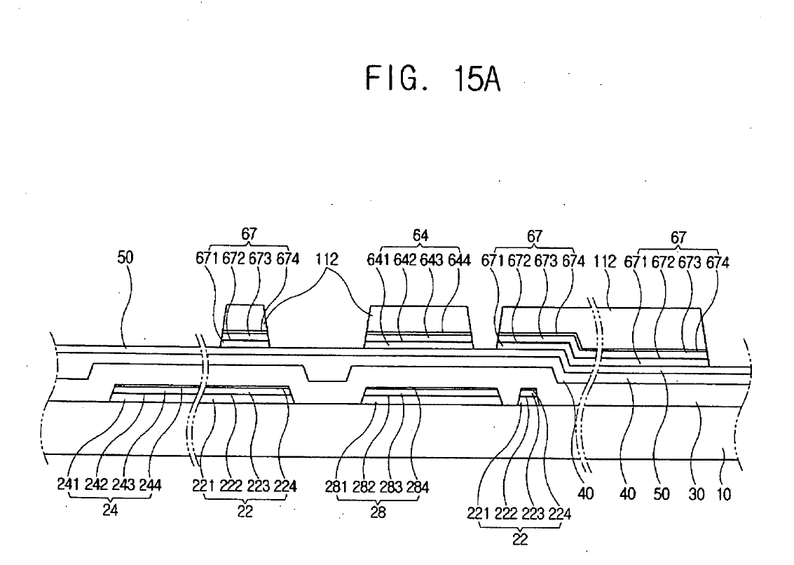

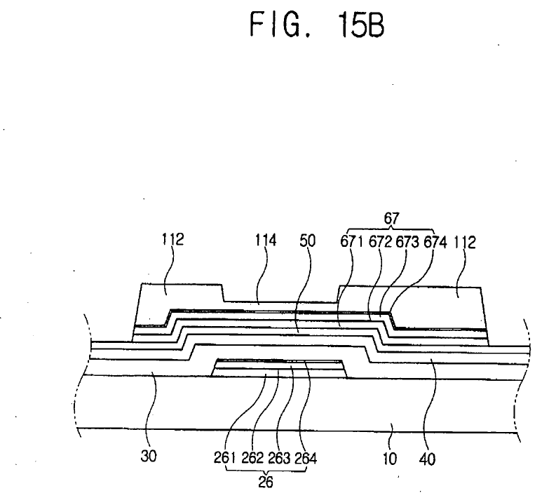

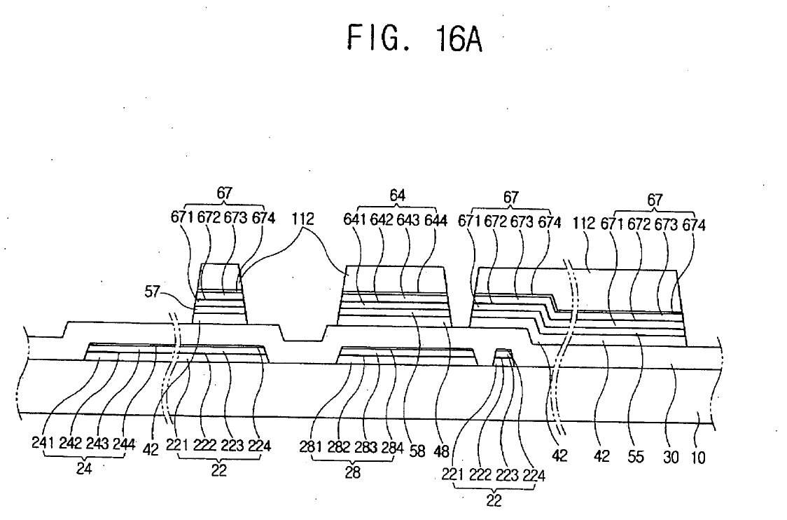

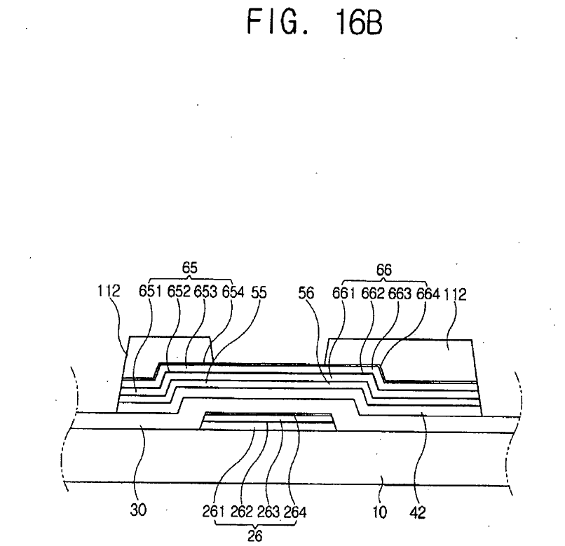

First, referring to FIGS. 14A and 14B, the conductive layer 60 exposed at the other portion B is removed, thereby exposing the underlying intermediate layer 50. According to an embodiment of the present invention, either a dry etching method or a wet etching method can be used for etching the conductive layer 60. Both etching methods are preferably performed under the conditions that prevent the photoresist pattern portions 112, 114 from being etched while the conductive layer 60 is etched. However, if the drying etching method is used, it is difficult to find proper conditions that do not etch the photoresist pattern portions 112, 114. Thus, the drying etching method is performed under conditions in which both the conductive layer 60 and the photoresist pattern portions 112, 114 are etched. In the dry etching method, the first photoresist pattern portion 114 is formed thicker than in the wet etching method in order to prevent the underlying conductive layer 60 from being exposed.

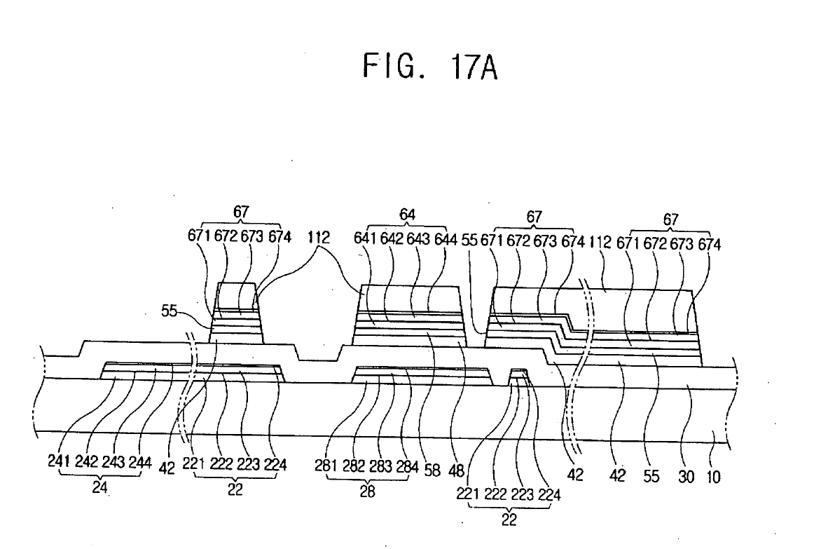

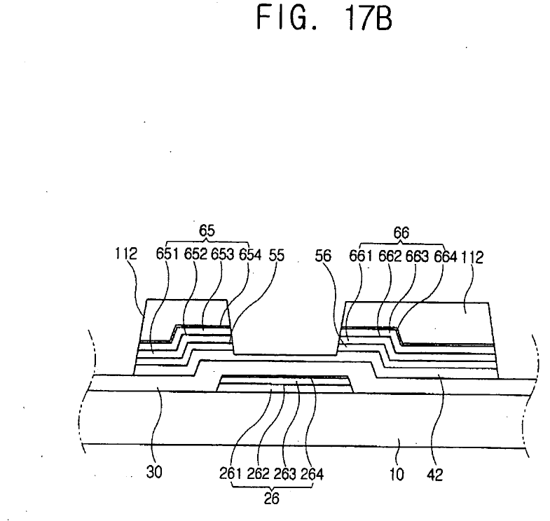

Consequently, as shown in FIGS. 15A and 15B, the conductive layer at the channel area C and the data wiring line area A is patterned. After the patterning, the source/drain conductive pattern 67 and the storage capacitor conductive pattern 64 remain whereas the conductive layer 60 placed at the other portion B is removed, thereby exposing the underlying intermediate layer 50. The left conductive patterns 67, 64 have a similar shape as the data wiring lines 62, 64, 65, 66, 68 except that source and drain electrodes 65 and 66 are not yet separated from each other. Furthermore, when the dry etching method is performed, the photoresist pattern portions 112 and 114 are also partially removed.

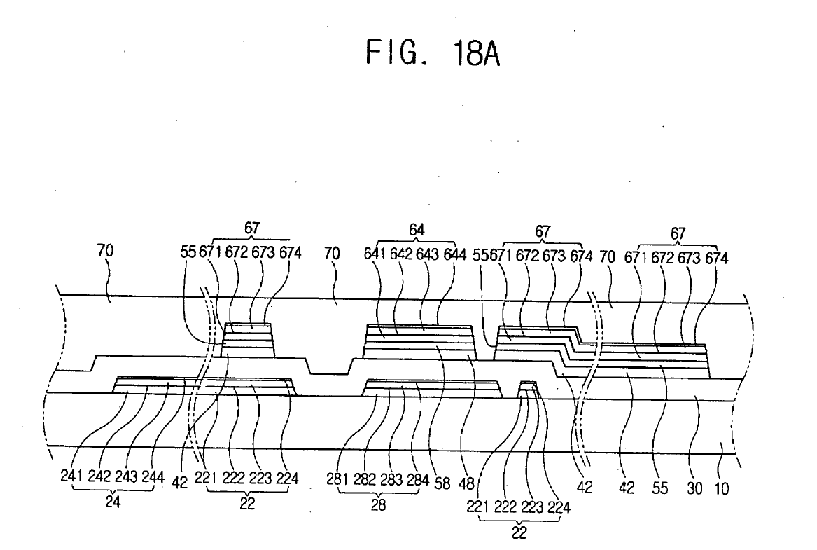

Referring to FIGS. 16A and 16B, the intermediate layer 50 exposed at the other portion B and the underlying semiconductor layer 40, together with the first photoresist pattern portion 114, are simultaneously removed by the dry etching method. The dry etching method is performed under conditions in which the photoresist pattern portions 112 and 114, the intermediate layer 50, and the semiconductor layer 40 (the semiconductor layer and the intermediate layer having no etching selectivity) are simultaneously etched while the gate insulating layer 30 is not etched. The dry etching method is preferably performed under the conditions in which the etching rates with respect to the photoresist patterns 112 and 114 and the semiconductor layer 40 are similar to each other. For example, a gas mixture of SF₆ and HCl, or SF₆ and O₂ is used to etch the photoresist pattern 112 (or 114) and the semiconductor layer 40 by substantially the same thickness. When the etching rates of the photoresist patterns 112 and 114 and the semiconductor layer 40 are the same or substantially the same, the thickness of the first photoresist pattern 114 is preferably the same as or less than the sum thickness of the semiconductor layer 40 and the intermediate layer 50.

Consequently, as shown in FIGS. 16A and 16B, the first photoresist pattern portion 114 at the channel portion C is removed, and the source/drain conductive pattern 67 is exposed. The intermediate layer 50 and the semiconductor layer 40 at the other portion B area are removed, and the underlying gate insulating layer 30 is exposed. Meanwhile, the second photoresist pattern portion 112 at the data wiring line portion C is also etched, so that the thickness thereof becomes thinner. Further, in this process, the semiconductor patterns 42 and 48 are formed. Reference numeral 57 and 58 indicate the intermediate pattern under the source/drain conductive pattern 67 and the intermediate pattern under the storage capacitor conductive pattern 64, respectively.

Then, The photoresist residue on the source/drain conductive pattern 67 at the channel portion C is removed through ashing.

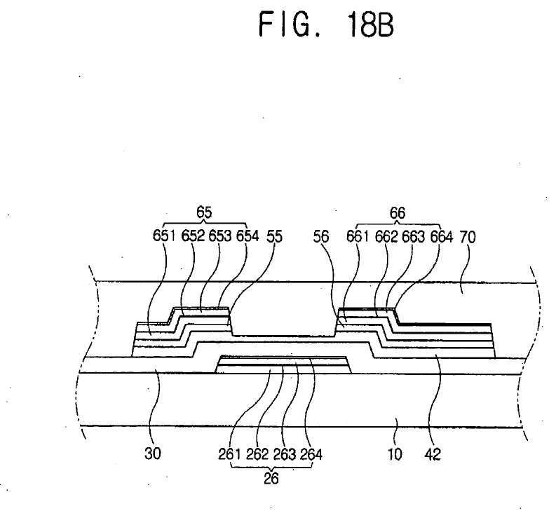

Referring to FIGS. 17A and 17B, the source/drain conductive pattern 67 and the source/drain intermediate layer pattern 57 at the channel portion C area are etched and removed. According to an embodiment of the present invention, the dry etching method is applied to both the source/drain conductive pattern 67 and the source/drain intermediate layer pattern 57. Alternatively, the wet etching method can be applied to the source/drain conductive pattern 67, and the dry etching method can be applied to the source/drain intermediate layer pattern 57. In the former case, it is preferable that the etching selectivity of the source/drain conductive pattern 67 to the source/drain intermediate layer pattern 57 is high. If the etching selectivity is not high enough, it is difficult to find the end point of the etching process and to control the thickness of the semiconductor pattern 42 remaining at the channel portion C. In the latter case, when the wet etching method and the dry etching method are alternated, the lateral sides of the source/drain conductive pattern 67 are etched by the wet etching method but the lateral sides of the source/drain intermediate layer pattern 57 is not substantially etched by dry etching. As a result, a cascade structure is formed. A gas mixture of CF₄ and HCl, or CF₄ and O₂ can be preferably used for etching the intermediate layer pattern 57 and the semiconductor pattern 42. When the gas mixture of CF₄ and O₂ is used, the semiconductor pattern 42 can have a uniform thickness. At this time, as shown in FIG. 16B, the semiconductor pattern 42 can be partially removed and becomes thinner, and the second photoresist pattern portions 112 is also etched by a predetermined thickness. The etching method should be performed under the conditions that the gate insulating layer 30 is not etched. It is preferable that the second photoresist pattern 112 is sufficiently thick as to prevent the underlying data wiring lines 62, 64, 65, 66, 68 from being exposed when etched.

The source electrodes 65 and the drain electrodes 66 are separated from each other, thereby completing the data wiring lines 62, 64, 65, 66, 68 and the underlying ohmic contact patterns 55, 56, 58.

Finally, the second photoresist pattern portion 112 remaining at the data wiring line area A is removed. Alternatively, the second photoresist pattern portion 112 can be removed before removing the underlying intermediate layer pattern 57 after removing the source/drain conductive pattern 67 at the channel portion C.

As described above, the wet etching method and the dry etching method can be used in combination, or only the dry etching method can be used. In the latter case, the process is simple but it is relatively difficult to find the proper etching conditions. In the former case, it is relatively easy to find the proper etching conditions but the process is complicated.

As shown in FIGS. 18A to 18B, the passivation layer 70 is formed by growing silicon nitride, a-Si:C:O layer or a-Si:O:F layer through the CVD method, or applying an organic insulating film.

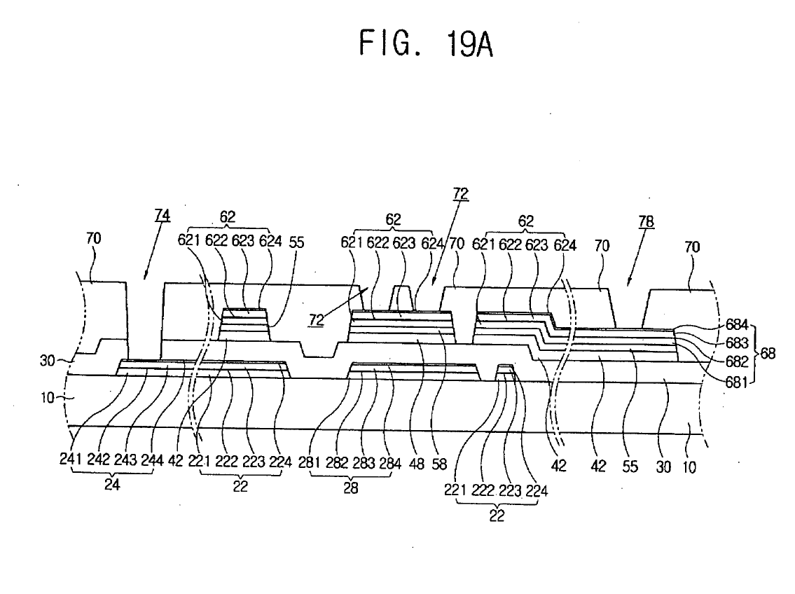

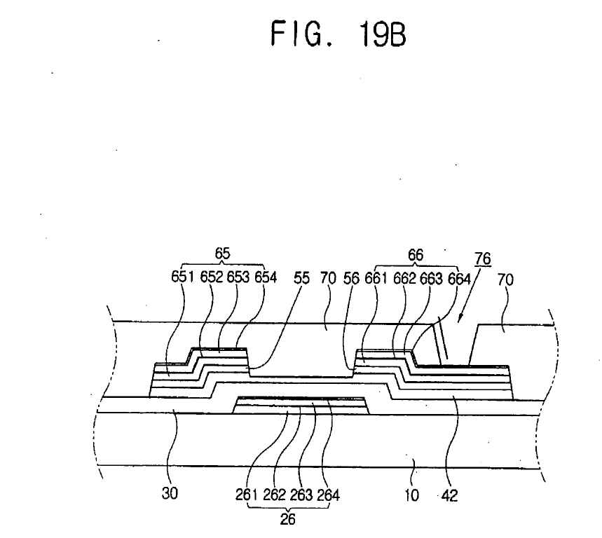

Referring to FIGS. 19A and 19B, the passivation layer 70, together with the gate insulating layer 30, is etched to form contact holes 76, 74, 78, 72 through which the drain electrodes 66, the end portion 24 of the gate line, the end portion 68 of the data line, and the storage capacitor conductive pattern 64 are exposed, respectively.

Finally, referring to FIGS. 10 and 11, the ITO layer or the IZO layer having a thickness of about 400 Å to about 500 Å is deposited and etched to form the pixel electrode 82 connected to the drain electrode 66 and the storage capacitor conductive pattern 64, and to form the contact subsidiary data part 88 connected to the end portion 24 of the gate line, the contact subsidiary gate part 86, and the end portion 68 of the data line.

Meanwhile, nitrogen gas can be used in a pre-heating process that is performed before depositing the ITO or IZO layer. The nitrogen gas prevents oxidation of the metal layers 24, 64, 66, 68 exposed through the contact holes 72, 74, 76, 78, respectively.

According to the second embodiment of the present invention, the data wiring lines 62, 64, 65, 66, 68, the underlying ohmic contact patterns 55, 56, 58, and the semiconductor patterns 42 and 48 are etched using one mask. At the same time, the source and drain electrodes 65 and 66 are separated from each other, thereby simplifying the fabricating process.

The present invention can be used in not only a TFT LCD but also an organic light emitting diode (OLED).

Here, the OLED uses an organic material that emits light in itself depending on a received electric signal. Such an OLED typically has a layered structure including an anode layer (pixel electrode), a hole injecting layer, a hole transporting layer, an emission layer, an electron transporting layer, an electron injection layer, and a cathode layer (counter electrode). According to an embodiment of the present invention, the drain electrode of the TFT array panel is electrically connected to the anode layer, thereby transmitting the data signal. On the other hand, the drain electrode of the TFT array panel can be electrically connected to the cathode layer.

As described above, the present invention provides a TFT array panel comprising an aluminum wiring line having an improved structure with reduced hillock formation and a fabricating method of the TFT array panel.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A TFT array panel comprising:
a lower aluminum layer;
an aluminum nitride layer formed on the lower aluminum layer; and
an upper aluminum layer formed on the aluminum nitride layer.

2. The TFT array panel according to claim 1, wherein the upper aluminum layer has a thickness of 2,500 Å or less.

3. The TFT array panel according to claim 3, wherein the upper aluminum layer has a thickness of 1,500 Å or less.

4. The TFT array panel according to claim 1, wherein the thickness sum of the lower and upper aluminum layers is greater than 4,000 Å.

5. The TFT array panel according to claim 1, wherein the thickness of the aluminum nitride layer is more than 5% of the thickness of the lower aluminum layer.

6. The TFT array panel according to claim 1, wherein the thickness of the aluminum nitride layer ranges from 100 to 400 Å.

7. The TFT array panel according to claim 1, further comprising a molybdenum layer formed on the upper aluminum layer.

8. The TFT array panel according to claim 1, wherein the aluminum nitride layer contains 0.01 to 60 mole % nitrogen.

9. A TFT array panel comprising:
a gate wiring line;
a data wiring line; and
at least one of the gate and data wiring lines comprising a lower aluminum layer, an aluminum nitride layer, an upper aluminum layer, formed in sequence.

10. The TFT array panel according to claim 9, further comprising a molybdenum layer formed on the upper aluminum layer.

11. The TFT array panel according to claim 9, wherein the thickness sum of the lower and upper aluminum layers is greater than 4,000 Å.

12. The TFT array panel according to claim 9, wherein the thickness of the aluminum nitride layer is more than 5% of the thickness of the lower aluminum layer.

13. The TFT array panel according to claim 9, wherein the thickness of the aluminum nitride layer ranges from 100 to 400 Å.

14. The TFT array panel according to claim 9, wherein the aluminum nitride layer contains 0.01 to 60 mole % nitrogen.

15. A method of fabricating a TFT array panel, comprising:
depositing a lower aluminum layer on an insulating substrate;
depositing an aluminum nitride layer on the lower aluminum layer in a nitrogen precursor gas atmosphere; and
depositing an upper aluminum layer on the aluminum nitride layer.

16. The method according to claim 15, further comprising depositing a molybdenum layer on the upper aluminum layer.

17. The method according to claim 15, wherein the upper aluminum layer, the aluminum nitride layer, and the lower aluminum layer are continuously deposited.

18. The method according to claim 15, wherein the aluminum nitride layer is deposited by a sputtering method.

19. The method according to claim 15, wherein the nitrogen precursor gas contains at least one selected from a group consisting of nitrogen, ammonia, nitric oxide, and nitric dioxide.

20. The method according to claim 15, wherein the nitrogen precursor gas contains at least one selected from a group consisting of nitrogen, ammonia, nitric oxide, and nitric dioxide, and is provided together with argon.

21. A liquid crystal display comprising:
a first substrate comprising a gate wiring line and a data wiring line, at least one of which comprises a lower aluminum layer, an aluminum nitride layer, and an upper aluminum layer that are formed in sequence.
a second substrate facing the first substrate; and
a liquid crystal layer placed between the first substrate and the second substrate.
